(19) United States
(12) Patent Application Publication
(10) Pub. No.: US 2026/0090015 A1
(43) Pub. Date: Mar. 26, 2026

(54) SELF ALIGNED BACKSIDE CONTACT

(71) Applicant: International Business Machines Corporation, Armonk, NY (US)

(72) Inventors: Min Gyu Sung, Latham, NY (US); Tao Li, Slingerlands, NY (US); Ruilong Xie, Niskayuna, NY (US); Nicolas Jean Loubet, GUILDERLAND, NY (US)

(21) Appl. No.: 18/892,810

(22) Filed: Sep. 23, 2024

(51) Int. Cl. H01L 29/417; H01L 29/06; H01L 29/423; H01L 29/775; H01L 29/786

(52) U.S. Cl. CPC H10D 30/6729; H10D 30/43; H10D 30/6735; H10D 30/6757; H10D 62/121

(57) ABSTRACT

A nanosheet semiconductor structure including a self-aligned backside contact, and a gate cut contact structure extending between two stacks stack of semiconducting layers and in electrical contact with the self-aligned backside contact and a source drain contact on a frontside, wherein a lateral dimension of the gate cut contact structure is less than a lateral dimension of the self-aligned backside contact.

### BACKGROUND

The present invention generally relates to semiconductor structures, and more particularly to nanosheet transistor structures having self-aligned backside contacts.

Complementary Metal-oxide-semiconductor (CMOS) technology is commonly used for field effect transistors (hereinafter “FET”) as part of advanced integrated circuits (hereinafter “IC”), such as central processing units (hereinafter “CPUs”), memory, storage devices, and the like. As demands to reduce the dimensions of transistor devices continue, nanosheet FETs help achieve a reduced FET device footprint while maintaining FET device performance. A nanosheet FET includes a plurality of stacked nanosheets extending between a pair of source drain epitaxial regions. The device may be a gate-all-around device or transistor in which the gate surrounds a portion of the nanosheet channel. A nanosheet device contains one or more layers of semiconductor channel material portions having a vertical thickness that is substantially less than its width.

### SUMMARY

According to an embodiment of the present invention, a semiconductor structure is provided. The semiconductor structure may include a self-aligned backside contact, and a gate cut contact structure extending between two stacks stack of semiconducting layers and in electrical contact with the self-aligned backside contact and a source drain contact on a frontside, where a lateral dimension of the gate cut contact structure is less than a lateral dimension of the self-aligned backside contact.

According to another embodiment of the present invention, a semiconductor structure is provided. The semiconductor structure may include a self-aligned backside contact, and a gate cut contact structure extending between two stacks stack of semiconducting layers and in electrical contact with the self-aligned backside contact and a source drain contact on a frontside, where a lateral dimension of the gate cut contact structure is less than a lateral dimension of the self-aligned backside contact.

According to another embodiment of the present invention, a semiconductor structure is provided. The semiconductor structure may include

### BRIEF DESCRIPTION OF THE DRAWINGS

The following detailed description, given by way of example and not intended to limit the invention solely thereto, will best be appreciated in conjunction with the accompanying drawings, in which:

FIG. 1, a top view of a generic structure is shown to provide spatial context to the different cross-sectional views and structural orientations of the semiconductor structures shown in the subsequent figures;

FIGS. 2 and 3 are cross-sectional views of the semiconductor structure during an intermediate step of a method of fabricating nanosheet transistor structures according to an exemplary embodiment;

FIGS. 4 and 5 are cross-sectional views of the semiconductor structure after forming a first mask and removing portions of the substrate according to an exemplary embodiment;

FIGS. 6 and 7 are cross-sectional views of the semiconductor structure after removing the first mask and forming an RX liner and RV metal fill according to an exemplary embodiment;

FIGS. 8 and 9 are cross-sectional views of the semiconductor structure after recessing the RV metal fill and forming shallow trench isolation regions according to an exemplary embodiment;

FIGS. 10 and 11 are cross-sectional views of the semiconductor structure after removing portions of the RX liner, removing portions of the nanosheet stacks, forming source drain regions, forming dielectric layer, and forming gate structures according to an exemplary embodiment;

FIGS. 12 and 13 are cross-sectional views of the semiconductor structure after forming gate cut contact structures, a middle-of-line, back-end-of-line, and attaching a carrier wafer according to an exemplary embodiment;

FIGS. 14 and 15 are cross-sectional views of the semiconductor structure after flipping the assembly and recessing the substrate according to an exemplary embodiment;

FIGS. 16 and 17 are cross-sectional views of the semiconductor structure after removing the etch stop layer and forming a backside dielectric layer according to an exemplary embodiment; and

FIGS. 18 and 19 are cross-sectional views of the semiconductor structure after removing exposed portions of the RX liner, forming a first backside wiring layer, and forming additional backside wiring layers according to an exemplary embodiment.

The drawings are not necessarily to scale. The drawings are merely schematic representations, not intended to portray specific parameters of the invention. For clarity and ease of illustration, scale of elements may be exaggerated. The drawings are intended to depict only typical embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Also, the term “sub-lithographic” may refer to a dimension or size less than current dimensions achievable by photolithographic processes, and the term “lithographic” may refer to a dimension or size equal to or greater than current dimensions achievable by photolithographic processes. The sub-lithographic and lithographic dimensions may be determined by a person of ordinary skill in the art at the time the application is filed.

The terms substantially, substantially similar, about, or any other term denoting functionally equivalent similarities refer to instances in which the difference in length, height, or orientation convey no practical difference between the definite recitation (e.g. the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

Complementary field effect transistors, including gate-all-around transistor devices and nanosheet transistor devices, have known advantages over conventional transistor structures in terms of density, performance, power consumption, and integration. However, fabricating device contacts on a backside of the wafer presents unique challenges. More specifically, for example, conventional backside contact fabrication techniques require complex backside via integration to prevent shorting between the substrate and backside contact.

The present invention generally relates to semiconductor structures, and more particularly to nanosheet transistor structures having self-aligned backside contacts. More specifically, the nanosheet transistor structures and associated method disclosed herein enable a novel solution for providing self-aligned backside device contacts without requiring complex backside via integration to prevent shorting between the substrate and backside contact. As such, the novel self-aligned backside device contacts disclosed herein provides an electrical connection between

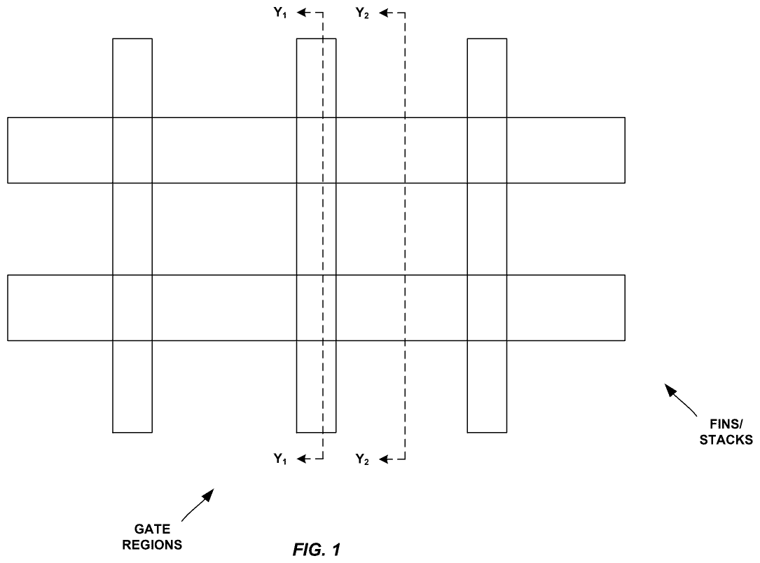

Exemplary embodiments of nanosheet transistor structures having self-aligned backside contacts are described in detail below by referring to the accompanying drawings in FIGS. 1 to 19. Those skilled in the art will readily appreciate that the detailed description given herein with respect to these figures is for explanatory purposes as the invention extends beyond these limited embodiments.

Referring now to FIG. 1, a top view of a generic structure is shown to provide spatial context to the different cross-sectional views and structural orientations of the semiconductor structures shown in the figures and described below. Additionally, XYZ Cartesian coordinates may be also shown in each of the drawings to provide additional spatial context. The terms “vertical” or “vertical direction” or “vertical height” as used herein denote a Z-direction of the Cartesian coordinates shown in the drawings, and the terms “horizontal,” or “horizontal direction,” or “lateral direction” as used herein denote an X-direction and/or a Y-direction of the Cartesian coordinates shown in the drawings.

The generic structure illustrated in FIG. 1 shows multiple fins/stacks and multiple gate regions situated perpendicular to one another. FIGS. 1-19 represent cross section views oriented as indicated in FIG. 1

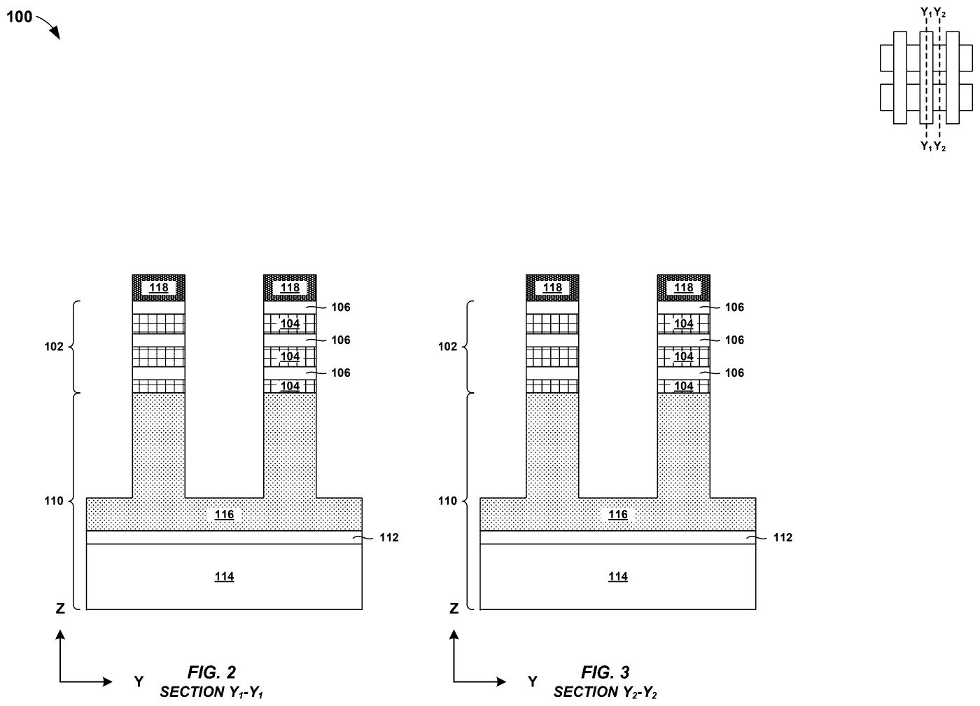

Referring now to FIGS. 2 and 3, a structure 100 is shown during an intermediate step of a method of fabricating a stacked transistor structure according to an embodiment of the invention. FIG. 2 depicts a cross-sectional view of the structure 100 taken along line Y₁-Y₁ and FIG. 3 depicts a cross-sectional view of the structure 100 taken along line Y₂-Y₂.

The structure 100 illustrated in FIGS. 2-3 includes nanosheet stacks 102, or fins, formed from an alternating series of first silicon germanium (SiGe) sacrificial nanosheets 104 (hereinafter “first sacrificial nanosheets 104”) and silicon (Si) channel nanosheets 106 (hereinafter “channel nanosheets 106”), as illustrated. The nanosheet stacks 102 are formed on a silicon substrate 110. Although only a limited number of nanosheet stacks 102 and nanosheet layers are shown, one or more additional nanosheet stacks and/or nanosheets can optionally be epitaxially grown in an alternating fashion, and the properties of any additional nanosheets are the same as the corresponding nanosheets described herein.

In one or more embodiments, the nanosheet stacks 102 are formed by epitaxially growing one layer and then the next until a desired number and a desired thickness of each layer is achieved. Epitaxial materials can be grown from gaseous or liquid precursors. Epitaxial materials can be grown using vapor-phase epitaxy (VPE), molecular-beam epitaxy (MBE), liquid-phase epitaxy (LPE), or other suitable process. Epitaxial silicon, silicon germanium, and/or carbon doped silicon (Si:C) can be undoped or can be doped during deposition (in-situ doped) by adding dopants, n-type dopants (e.g., phosphorus or arsenic) or p-type dopants (e.g., boron or gallium), depending on the type of transistor. For example, in at least one embodiment, each nanosheet stack 102 includes channel nanosheets 106 which are doped, undoped or some combination thereof.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases are controlled and the system parameters are set so that the depositing atoms arrive at the deposition surface with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed. For example, an epitaxially grown semiconductor material deposited on a {100} orientated crystalline surface will take on a {100} orientation. In some embodiments, epitaxial growth and/or deposition processes are selective to forming on semiconductor surfaces, and generally do not deposit material on exposed surfaces, such as silicon dioxide or silicon nitride surfaces.

In some embodiments, the gas source for the deposition of epitaxial semiconductor material includes a silicon containing gas source, a germanium containing gas source, or a combination thereof. For example, an epitaxial silicon layer can be deposited from a silicon gas source that is selected from the group consisting of silane, disilane, trisilane, tetrasilane, hexachlorodisilane, tetrachlorosilane, dichlorosilane, trichlorosilane, methylsilane, dimethylsilane, ethylsilane, methyldisilane, dimethyldisilane, hexamethyldisilane and combinations thereof. An epitaxial germanium layer can be deposited from a germanium gas source that is selected from the group consisting of germane, digermane, halogermane, dichlorogermane, trichlorogermane, tetrachlorogermane and combinations thereof. While an epitaxial silicon germanium alloy layer can be formed utilizing a combination of such gas sources. Carrier gases like hydrogen, nitrogen, helium and argon can be used.

The substrate 110 may be a layered semiconductor such as a silicon-on-insulator or SiGe-on-insulator, where an etch stop layer 112, separates a base substrate 114 from a top semiconductor layer 116. Unlike conventional layered semiconductor substrates, the etch stop layer 112 of the substrate 110 may include any material which affects the desired etch selectivity during subsequent processing. For example, the etch stop layer 112 may be a conventional buried oxide layer, or it may be a silicon germanium layer with a specific germanium concentration. In practice, the etch stop layer 112 will function as an etch stop layer and can be composed of any material which supports that function.

In the present embodiment, both the base substrate 114 and the top semiconductor layer 116 may be any bulk substrate made from any of several known semiconductor materials such as, for example, silicon, germanium, silicon-germanium alloy, and compound (e.g. III-V and II-VI) semiconductor materials. For example, both the base substrate 114 and the top semiconductor layer 116 may be made from silicon. Additionally, both the etch stop layer 112 and the base substrate 114 are sacrificial and will not remain in the final structure.

Known processing techniques have been applied to the alternating layers to form the nanosheet stacks 102 shown. For example, the known processing techniques can include the formation of hard masks 118 over the topmost layer of the nanosheet stacks 102. The hard masks 118 can be formed by first depositing the hard mask material (for example silicon nitride) onto the topmost layer of the nanosheet stack 102 using, for example, chemical vapor deposition (CVD), plasma enhanced CVD (PECVD) or any suitable technique for dielectric deposition that does not induce a physical or chemical change to the topmost layer of the nanosheet stack 102. According to an exemplary embodiment, the hard mask material is deposited onto the channel nanosheets 106 at the top of the nanosheet stack 102 and then patterned into a plurality of the individual hard masks (118). Patterning the hard mask material is commensurate with a desired footprint and location of the nanosheet stacks 102, as illustrated, which will subsequently be used to form the channel regions of semiconductor devices disclosed herein. According to an exemplary embodiment, reactive ion etching (RIE) is used to transfer the hard mask pattern into the alternating layers to form the nanosheet stacks 102, and into the substrate 110, as shown.

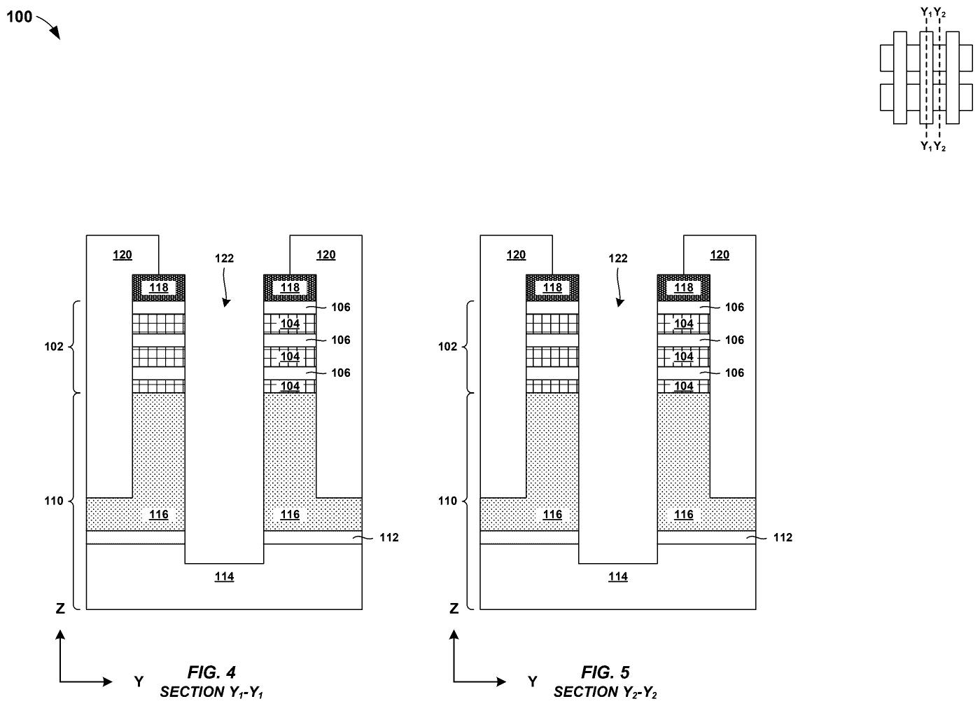

Referring now to FIGS. 4 and 5, a structure 100 is shown after forming a first mask 120 and removing portions of the substrate 110 according to an embodiment of the invention. FIG. 4 depicts a cross-sectional view of the structure 100 taken along line Y₁-Y₁ and FIG. 5 depicts a cross-sectional view of the structure 100 taken along line Y₂-Y₂.

First, the first mask 120 is deposited and subsequently patterned to expose certain portions of the structure 100 according to known techniques. Specifically, portions between the nanosheet stacks 102 in regions designated rear vias (RV) are exposed, as illustrated. Generally, rear vias provide an electrical connection from the frontside of the structure 100 to the backside of the structure 100. Such rear vias are typically positioned between adjacent nanosheet stacks 102.

The first mask 120 can be an organic planarization layer (OPL) or a layer of material that is capable of being planarized or etched by known techniques. In an embodiment, for example, the first mask 120 can be an amorphous carbon layer able to withstand subsequent processing temperatures. The first mask 120 can preferably have a thickness sufficient to cover existing structures. After deposition of the first mask 120, a dry etching technique is applied to pattern the first mask 120 according to known techniques.

Next, portions of the substrate 110 in regions designated for rear vias are removed to form trenches 122 according to known techniques. Specifically, exposed portions of the top semiconductor layer 116, the etch stop layer 112, and the base substrate 114 are removed using known etching techniques, as illustrated. In an embodiment, the portions of the substrate 110 are removed using an anisotropic etch such as, for example, reactive ion etching. Critical to the disclosed embodiments, etching shall continue until at least the base substrate 114 is exposed. In a preferred embodiment etching continues until portions of the base substrate 114 are removed, and the trenches 122 extend some depth into the base substrate 114.

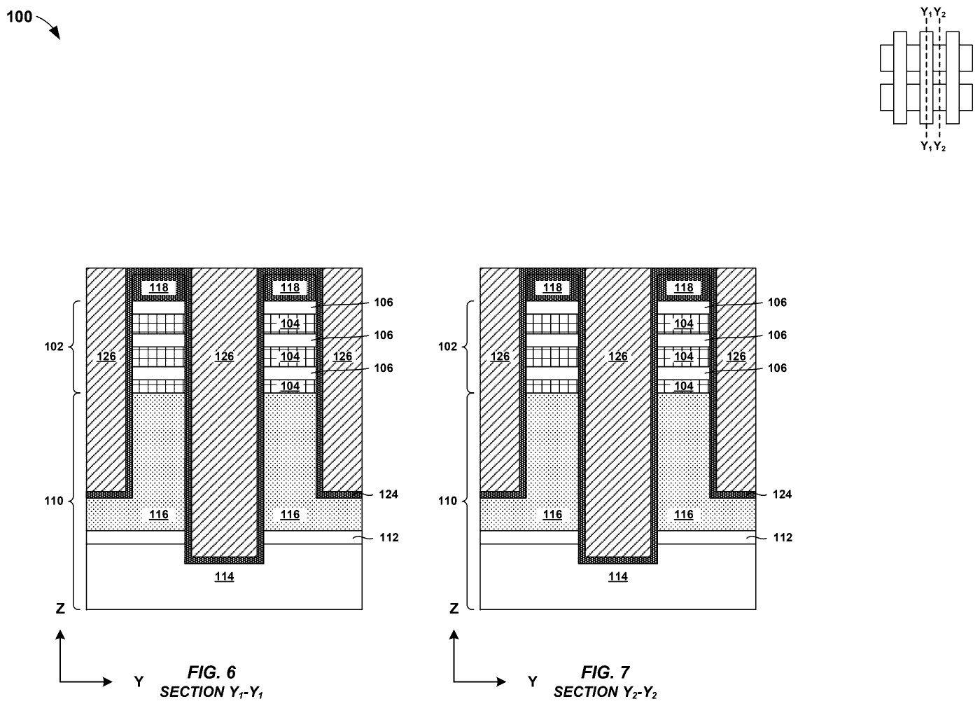

Referring now to FIGS. 6 and 7, a structure 100 is shown after removing the first mask 120 and forming an RX liner 124 and RV metal fill 126 according to an embodiment of the invention. FIG. 6 depicts a cross-sectional view of the structure 100 taken along line Y₁-Y₁ and FIG. 7 depicts a cross-sectional view of the structure 100 taken along line Y₂-Y₂.

First, the first mask 120 is removed according to known techniques. Next, the RX liner 124 is conformally deposited directly on exposed surfaces of the structure 100 according to known techniques. Specifically, for example, a relatively thin layer of silicon nitride (SiN) is conformally deposited over and around the nanosheet stacks 102 and within the trenches 122, as illustrated. In some embodiments, for example, the RX liner 124 may be composed of SiN, SiBCN, SiOCN, SiOC, or any other combination of low-k materials. The term “low-k” as used throughout the present application denotes a dielectric material that has a dielectric constant of less than 4.0.

Next, the RV metal fill 126 is blanket deposited directly on top of the RX liner 124 and around the nanosheet stacks 102 according to known techniques. Specifically, the RV metal fill 126 may include any suitable conductive material, such as, for example, copper, ruthenium, aluminum, tungsten, cobalt, or alloys thereof.

After the RV metal fill 126 is deposited, the structure 100 is polished according to known techniques, such as, for example, chemical mechanical polishing techniques. Specifically, polishing continues until a topmost surface of the RV metal fill 126 is flush, or substantially flush, with topmost surfaces of the RX liner 124. As shown, and critical to the disclosed embodiments, the RX liner 124 isolates the RV metal fill 126 the top semiconductor layer 116.

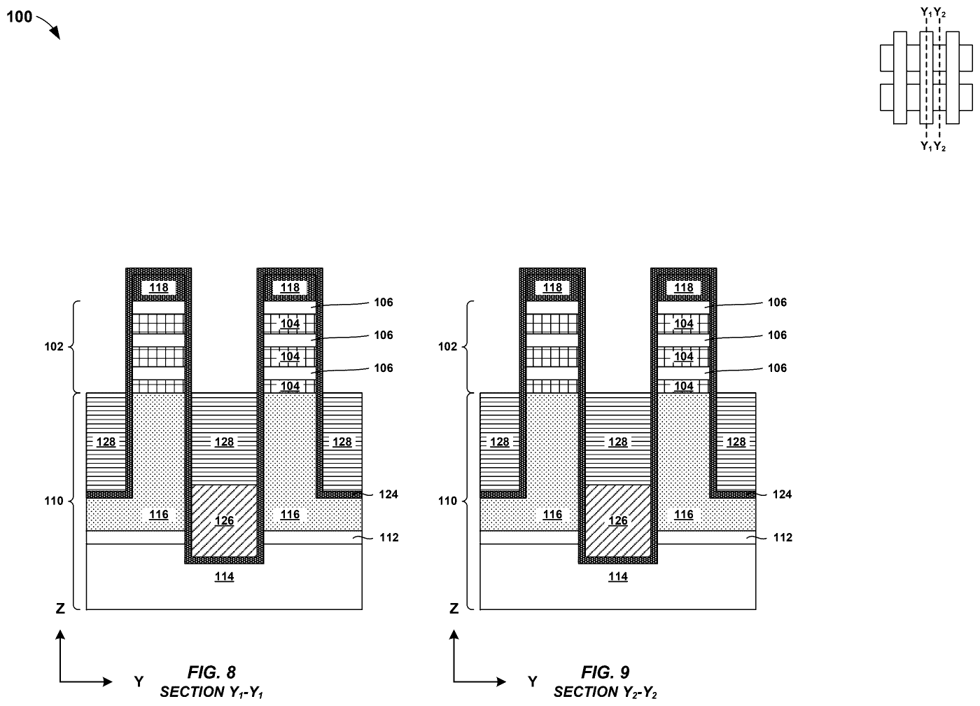

Referring now to FIGS. 8 and 9, a structure 100 is shown after recessing the RV metal fill 126 and forming shallow trench isolation regions 128 (hereinafter “STI regions 128”) according to an embodiment of the invention. FIG. 8 depicts a cross-sectional view of the structure 100 taken along line Y₁-Y₁ and FIG. 9 depicts a cross-sectional view of the structure 100 taken along line Y₂-Y₂.

First, the RV metal fill 126 is recessed according to known techniques. Specifically, portions of the RV metal fill 126 are etched or removed selective to the RX liner 124, as illustrated. The portions of the RV metal fill 126 can be removed using reactive ion etching. Etching, or recessing, of the RV metal fill 126 shall continue until top surfaces of the RX liner 124 are exposed in regions not designated for rear vias. In contrast, a portion of the RV metal fill 126 shall remain in the trenches 122 in regions designated for rear vias.

Next, the STI regions 128 are formed according to known techniques. The STI regions 128 are formed at the bottom of trenches in the substrate 110 formed during patterning of the nanosheet stacks 102. Specifically, a dielectric material is deposited at the bottom of trenches in the substrate 110 and then subsequently recessed using known techniques. The STI regions 128 isolate adjacent devices from one another according to known techniques. The STI regions 128 may be formed from any appropriate dielectric material including, for example, silicon oxide (SiOₓ) or silicon nitride (SiₓN_{y}). According to an embodiment, the RX liner 124 is made from silicon nitride and the STI regions 128 are made from silicon oxide.

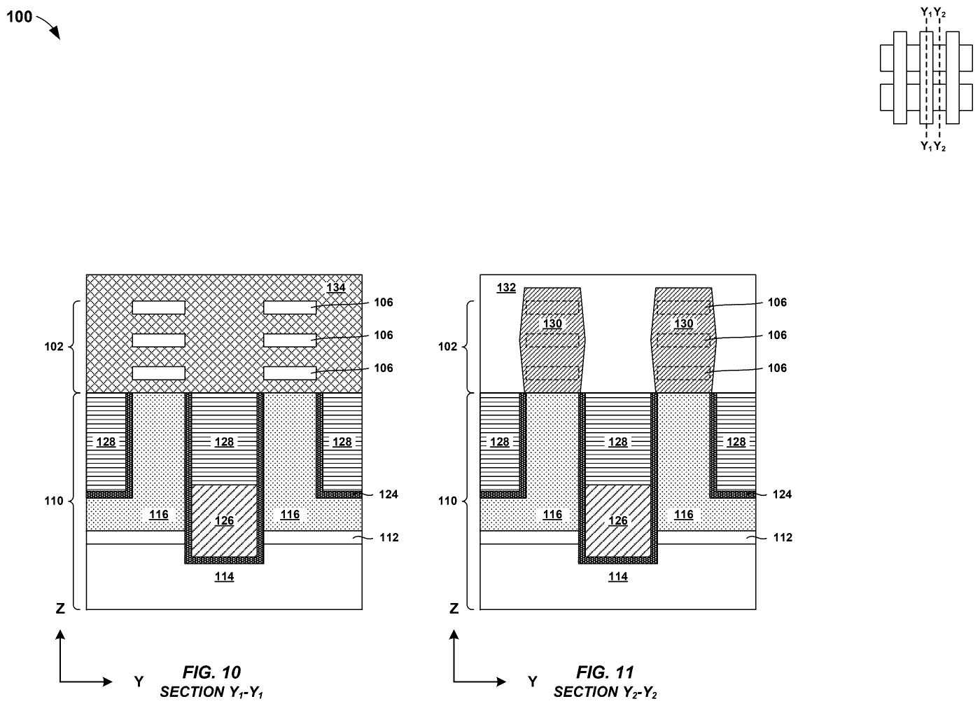

Referring now to FIGS. 10 and 11, a structure 100 is shown after removing portions of the RX liner 124, removing portions of the nanosheet stacks 102, forming source drain regions 130, forming dielectric layer 132, and forming gate structures 134 according to an embodiment of the invention. FIG. 10 depicts a cross-sectional view of the structure 100 taken along line Y₁-Y₁ and FIG. 11 depicts a cross-sectional view of the structure 100 taken along line Y₂-Y₂.

First, portions of the RX liner 124 are etched and removed to expose the nanosheet stacks 102 according to known techniques. Specifically, exposed portions of the RX liner 124 are removed using known etching techniques suitable to remove, for example, silicon nitride selective to the nanosheet stacks 102. In an embodiment, the portions of the RX liner 124 are removed using an isotropic etch such as, for example, wet etch.

Next, sacrificial gates (not shown) are formed perpendicular to the nanosheet stacks 102, and portions of the nanosheet stacks 102 are etched and removed from between the sacrificial gates according to known techniques. Specifically, portions of the nanosheet stacks 102 are removed using an anisotropic etch such as, for example, reactive ion etching. Doing so may require a series of multiple etching steps using different etch chemistries as is well known in the art. Etching is designed to define source drain regions and expose ends of individual nanosheet layers. In all cases, etching continues until the substrate 110 is exposed, as illustrated. Turning to the figures, portions of the nanosheet stacks 102 are removed in FIG. 11, and remain in FIG. 10.

Next, the source drain regions 130 are formed using an epitaxial layer growth process on the exposed ends of the channel nanosheets 106 according to known techniques. Typically, in-situ doping is used to dope the source drain regions 130, thereby creating the necessary junctions of the semiconductor device. Virtually all semiconductor transistors are based on the formation of junctions. Junctions are capable of both blocking current and allowing it to flow, depending on an applied bias. Junctions are typically formed by placing two semiconductor regions with opposite polarities into contact with one another. The most common junction is the p-n junction, which consists of a contact between a P-type piece of silicon, rich in holes, and an N-type piece of silicon, rich in electrons. N-type and P-type devices are formed by using different types of dopants to select regions of the device to form the necessary junction(s). For example, N-type devices can be formed by doping with arsenic (As) or phosphorous (P), and p-type devices can be formed by doping with implanting boron (B).

Next, the dielectric layer 132 is formed by blanket depositing an interlayer dielectric material over the structure 100 according to known techniques. Specifically, the dielectric layer 132 is formed on the source drain regions 130 and substantially fills the remaining space between the nanosheets stacks 102 and the source drain regions 130, as illustrated.

The dielectric layer 132 can be composed of silicon dioxide, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. In another embodiment, a self-planarizing material such as a spin-on glass (SOG) or a spin-on low-k dielectric material such as SiLK™ can be used as the dielectric layer 132. Using a self-planarizing dielectric material as the dielectric layer 132 can avoid the need to perform a subsequent planarizing step.

Next, the gate structures 134 are formed according to known techniques. First, the sacrificial gates and the sacrificial nanosheets 104 are selectively removed. Next, a gate dielectric (not shown) is conformally deposited directly on exposed surfaces of the structure 100 within gate cavities or openings and spaces left by removing the sacrificial gates and the sacrificial nanosheets 104 according to known techniques.

The gate dielectric is composed of any known gate dielectric materials, for example, oxide, nitride, and/or oxynitride. In an example, the gate dielectric can be a high-k material having a dielectric constant greater than silicon dioxide. Exemplary high-k dielectrics include, but are not limited to, HfO₂, ZrO₂, La₂O₃, Al₂O₃, TiO₂, SrTiO₃, LaAlO₃, Y₂O₃, HfOₓN_{y}, ZrOₓN_{y}, La₂OₓN_{y}, Al₂OₓN_{y}, TiOₓN_{y}, SrTiOₓN_{y}, LaAlOₓN_{y}, Y₂OₓN_{y}, SiON, SiNₓ, a silicate thereof, and an alloy thereof. Each value of x is independently from 0.5 to 3 and each value of y is independently from 0 to 2. In some embodiments, a multilayered gate dielectric structure including different gate dielectric materials. For example, a silicon dioxide layer and a high-k gate dielectric layer can be formed and used together as the gate dielectric. In at least one embodiment, the gate dielectric is composed of hafnium oxide.

Next, a work function metal (not shown) is conformally deposited on the gate dielectric formed within the gate cavities according to known techniques. In at least one embodiment, the work function metal is made of the same conductive material across the entire structure. In at least another embodiment, the work function metal is made from different conductive materials in each of the devices illustrated the figures. In doing so, the different conductive materials would be deposited successively according to the design parameters and desired operation characteristics.

The work function metal can include any known conductive gate material including, for example, doped polysilicon, an elemental metal (e.g., tungsten, titanium, tantalum, aluminum, nickel, ruthenium, palladium and platinum), an alloy of at least two elemental metals, an elemental metal nitride (e.g., tungsten nitride, aluminum nitride, and titanium nitride), an elemental metal silicide (e.g., tungsten silicide, nickel silicide, and titanium silicide), or titanium carbon (TiC), titanium aluminum (TiAl), titanium aluminum carbon (TiAlC), or multilayered combinations thereof. In some embodiments, the work function metal can include an nFET gate metal. In other embodiments, the work function metal can include a pFET gate metal. When multiple gate cavities are formed, as illustrated herein, embodiments of the present invention explicitly contemplate forming an nFET in at least one of the gate cavities and a pFET in at least another one of the gate cavities.

In some embodiments, gate metal or contact metal, is deposited directly on the work function metal, and fills the gate cavities. The first gate metal may include any suitable conductive material, such as, for example, copper, ruthenium, aluminum, tungsten, cobalt, or alloys thereof. After, excess conductive material can be polished using known techniques.

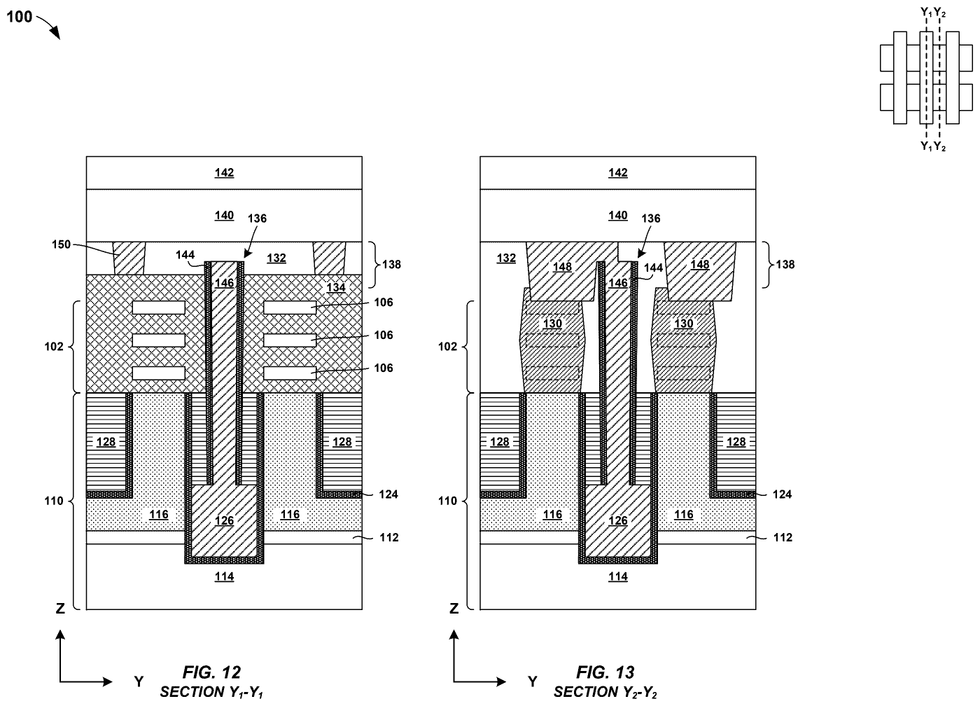

Referring now to FIGS. 12 and 13, a structure 100 is shown after forming gate cut contact structures 136, a middle-of-line 138, back-end-of-line 140, and attaching a carrier wafer 142 according to an embodiment of the invention. FIG. 12 depicts a cross-sectional view of the structure 100 taken along line Y₁-Y₁ and FIG. 13 depicts a cross-sectional view of the structure 100 taken along line Y₂-Y₂.

The gate cut contact structures 136 are conductive features which extend through the device region, or front-end-of-line, through the STI regions 128, and provide a conductive path between the frontside and the backside of the structure 100 as referenced herein. The function and/or purpose of such a conductive path will become apparent in subsequent description. Typically, the gate cut contact structures each include a contact liner 144 and a contact fill 146 as is known and according to an embodiment of the invention. In an embodiment, the contact liner 144 is silicon nitride; however, other suitable dielectric liner materials may also be used. Meanwhile, according to disclose embodiments, the contact fill 146 is copper or tungsten; however, other suitable conductive materials may also be used.

According to the embodiments disclosed herein, the gate cut contact structures 136 may also function to isolate, or separate, individual gate regions, as illustrated. For example, each individual gate region may include a single nanosheet stack 102 or multiple nanosheet stacks 102 having a common gate (134). Additionally, the different nanosheet stacks 102 separated by the gate cut contact structures 136 may be N-type, P-type, or any combination thereof. Finally, the gate cut contact structures 136 can be positioned anywhere according to a desired design and are not necessarily limited to the positions and configurations depicted and described herein.

The middle-of-line 138 includes source drain contacts 148 and gate contacts 150 which may be generally referred to as middle-of-line contacts. The source drain contacts 148 and the gate contacts 150 are formed according to known techniques. First, additional interlayer dielectric material is deposited according to known techniques. The dielectric layer 132 illustrated in the figures includes the additional interlayer dielectric material. Next, portions of the dielectric layer 132 are removed to expose the source drain regions 130. The openings are then filled with a conductive material to form the middle-of-line contacts according to known techniques. The middle-of-line contacts include any suitable conductive material, such as, for example, copper, ruthenium, aluminum, tungsten, cobalt, or alloys thereof. In some embodiments, a metal silicide is formed at the bottom of the contact trenches prior to filling them with the conductive material.

The back-end-of-line 140 may include vias and metal lines which may be generally referred to as back-end-of-line interconnects. The vias and the metal lines are formed according to known techniques.

Finally, the carrier wafer 142 is secured to a top of the structure 100 according to an embodiment of the invention. The carrier wafer 142 is attached, or removably secured, to the back-end-of-line 140. In general, and not depicted, the carrier wafer 142 may be thicker than the other layers. Temporarily bonding the structure 100 to a thicker carrier provides improved handling and additional support for backside processing of thin wafers. After backside processing described below, the structure 100 may be de-bonded, or removed, from the carrier wafer 142 according to known techniques.

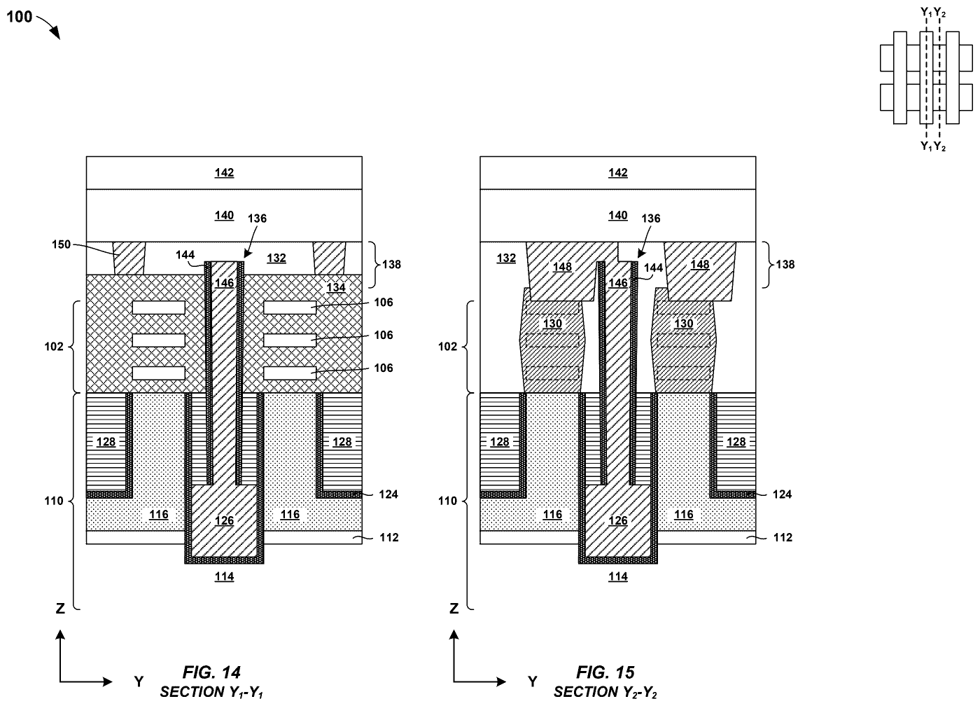

Referring now to FIGS. 14 and 15, a structure 100 is shown after flipping the assembly and recessing the substrate 110 according to an embodiment of the invention. FIG. 14 depicts a cross-sectional view of the structure 100 taken along line Y₁-Y₁ and FIG. 15 depicts a cross-sectional view of the structure 100 taken along line Y₂-Y₂.

First, the structure 100 is flipped 180 degrees to prepare for backside processing. In general, backside processing includes fabrication or processing of the structure 100 opposite the active device and wiring layers. Next, the substrate 110 is recessed according to known techniques. Specifically, the base substrate 114 is recessed or completely removed to expose the etch stop layer 112, as shown. It is noted, the orientation of the cross-sectional views referenced and illustrated hereafter will remain unchanged despite the actualities of flipping of the structure 100 for purposes of fabrication. As such, all references to “upper”, “lower”, “right”, “left”, “vertical”, “horizontal”, “top”, “bottom”, and derivatives thereof shall continue to relate to the disclosed structures and methods, as oriented in the drawing figures.

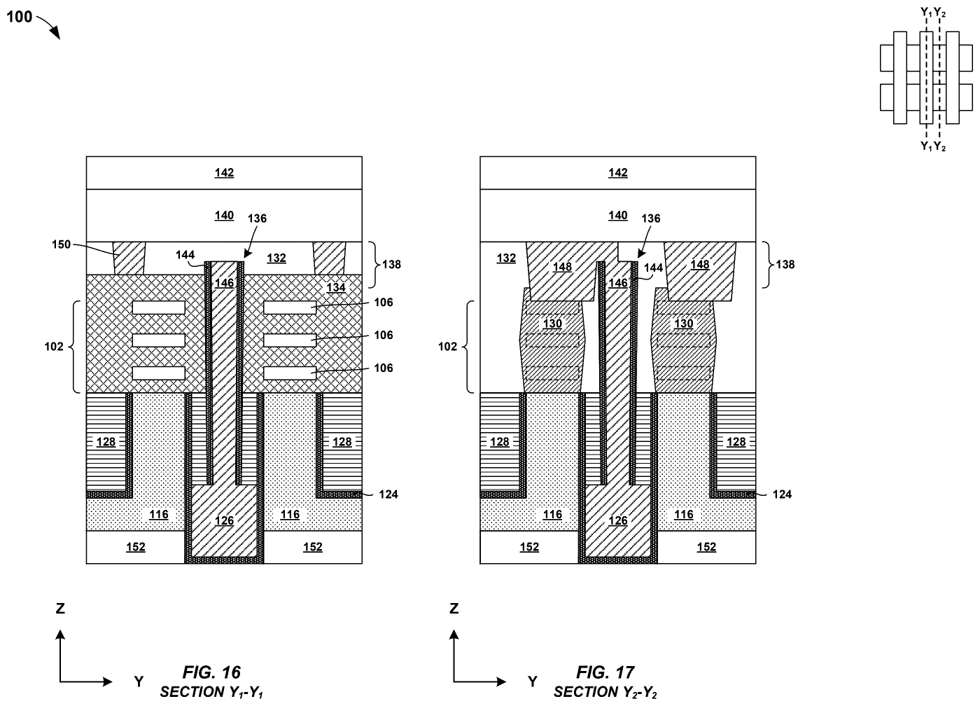

Referring now to FIGS. 16 and 17, a structure 100 is shown after removing the etch stop layer 112 and forming a backside dielectric layer 152 according to an embodiment of the invention. FIG. 16 depicts a cross-sectional view of the structure 100 taken along line Y₁-Y₁ and

FIG. 17 depicts a cross-sectional view of the structure 100 taken along line Y₂-Y₂. The etch stop layer 112 is selectively removed and the top semiconductor layer 116 is recessed according to known techniques. Specifically, the etch stop layer 112 is removed selective to the top semiconductor layer 116 and the top semiconductor layer 116 substantially remains, as illustrated.

Next, the backside dielectric layer 152 is formed across the backside of the structure 100 according to known techniques. Specifically, a backside dielectric material is blanket deposited across exposed surfaces on the backside of the structure 100. In an embodiment, for example, the backside dielectric layer 152 is made from a similar material as the dielectric layer 132. After deposition, excess dielectric material can be polished using known techniques until bottommost surfaces of the backside dielectric material are flush, or substantially flush, with bottommost surfaces of the RX liner 124, as illustrated.

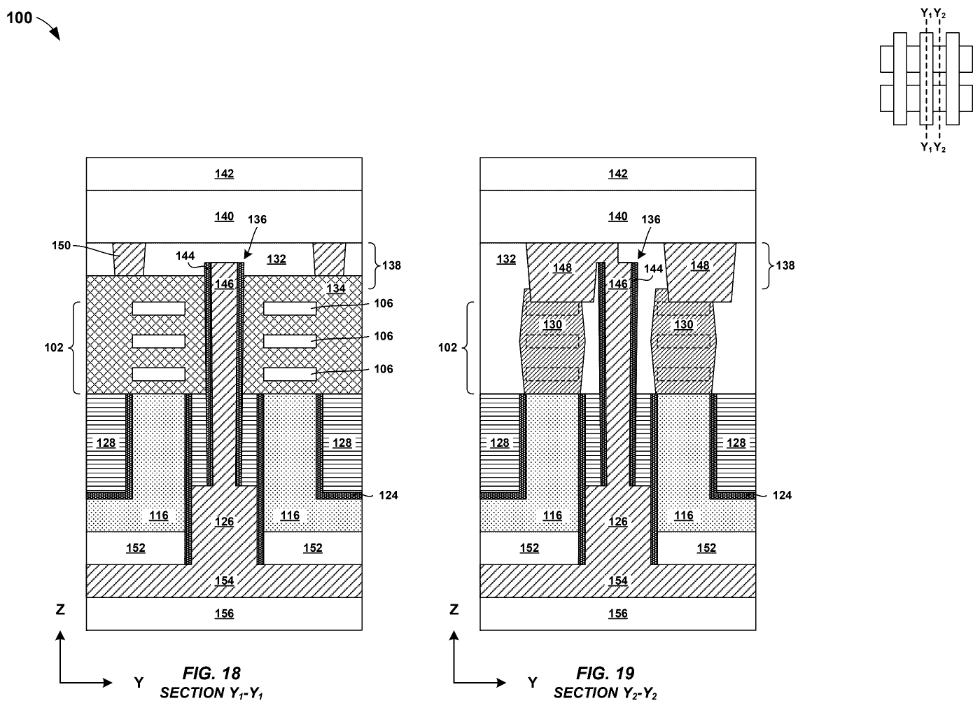

Referring now to FIGS. 18 and 19, a structure 100 is shown after removing exposed portions of the RX liner 124, forming a first backside wiring layer 154, and forming additional backside wiring layers 156 according to an embodiment of the invention. FIG. 18 depicts a cross-sectional view of the structure 100 taken along line Y₁-Y₁ and FIG. 19 depicts a cross-sectional view of the structure 100 taken along line Y₂-Y₂.

First, exposed portions of the RX liner 124 are removed to expose the RV metal fill 126 according to known techniques. For example, known directional or anisotropic etching techniques are used to remove exposed portions of the RX liner 124 across the backside of the structure 100. In an alternative embodiment, masking techniques may be used to limit etch to certain regions of the structure 100. Etching shall continue until at least the RV metal fill 126 is exposed. At this stage of fabrication the RV metal fill 126 may be referred to as a self-aligned backside contact 126 which was both fabricated from the frontside and not using a backside via process.

Finally, the first backside wiring layer 154 and the additional backside wiring layers 156 are formed according to an embodiment of the invention. Specifically, the first backside wiring layer 154 includes conductive interconnects, some of which directly contact the RV metal fill 126, as illustrated. The first backside wiring layer 154 may alternatively be referred to as the first metal level on the backside of the structure 100, or the first backside metal level.

Together, both the first backside wiring layer 154 and the additional backside wiring layers 156 may collectively be referred to as backside wiring generally. In addition, the backside wiring may also include backside power rails and/or a backside power delivery network.

According to the embodiment illustrated in FIGS. FIGS. 18 and 19, the transistor structures represented by the structure 100 have some distinctive notable features. For instance, the self-aligned backside contact 126 and the contact fill 146 together form an electrical connection between the source drain contacts 148 located the first backside wiring layer 154, on the backside, without requiring backside via patterning. In doing so, the self-aligned backside contact 126 and the RX liner 124 directly contact a top of the first backside wiring layer 154 without any intervening vias. Therefore, the disclosed embodiments avoid complex backside via integration and eliminate the risk of shorting between the substrate and backside contact.

It is noted, due to the fabrication order, the RX liner 124 lines sidewalls of both the STI regions 128 and the self-aligned backside contact 126, and a lateral width of the self-aligned backside contact 126 is substantially equal to a lateral width of one of the STI regions 128. Critical to the disclosed embodiments, the RX liner 124 physically separates and electrically isolates the self-aligned backside contact 126 from the substrate 110, specifically, the remaining portions of the top semiconductor layer 116.

Additionally, a lateral dimension of the gate cut contact structure 136 is less than a lateral dimension of the self-aligned backside contact 126. The contact liner 144 surrounding the contact fill 146 directly contacts a top surface of the self-aligned backside contact 126.

With continued reference to FIGS. 18 and 19, and according to an embodiment, the structure 100 includes a self-aligned backside contact, and a gate cut contact structure extending between two stacks stack of semiconducting layers and in electrical contact with the self-aligned backside contact and a source drain contact on a frontside, where a lateral dimension of the gate cut contact structure is less than a lateral dimension of the self-aligned backside contact.

With continued reference to FIGS. 18 and 19, and according to an embodiment, the gate cut contact structure further includes a contact liner, and a contact fill.

With continued reference to FIGS. 18 and 19, and according to an embodiment, a portion of the contact liner is sandwiched between the source drain contact on a frontside and the contact fill of the gate cut contact structure.

With continued reference to FIGS. 18 and 19, and according to an embodiment, the contact liner of the gate cut contact structure directly contacts a top surface of the self-aligned backside contact.

With continued reference to FIGS. 18 and 19, and according to an embodiment, an RX liner physically separates and electrically isolates the self-aligned backside contact from a surrounding semiconductor layer.

With continued reference to FIGS. 18 and 19, and according to an embodiment, the self-aligned backside contact and an RX liner directly contact a top of a first backside wiring layer.

With continued reference to FIGS. 18 and 19, and according to an embodiment, an RX liner lines sidewalls of both the shallow trench isolation region and the self-aligned backside contact.

With continued reference to FIGS. 18 and 19, and according to an embodiment, the structure 100 a self-aligned backside contact, and a gate cut contact structure extending between two stacks stack of semiconducting layers and in electrical contact with the self-aligned backside contact and a source drain contact on a frontside, where a lateral dimension of the gate cut contact structure is less than a lateral dimension of the self-aligned backside contact.

With continued reference to FIGS. 18 and 19, and according to an embodiment, the structure 100 includes a shallow trench isolation region arranged between a first stack of semiconducting layers and a second stack of semiconducting layers, a self-aligned backside contact, where a lateral width of the self-aligned backside contact is substantially equal to a lateral width of the shallow trench isolation region, and a gate cut contact structure extending from the self-aligned backside contact to a source drain contact on a frontside through the shallow trench isolation region.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A nanosheet semiconductor structure comprising:
a self-aligned backside contact; and
a gate cut contact structure extending between two stacks stack of semiconducting layers and in electrical contact with the self-aligned backside contact and a source drain contact on a frontside, wherein a lateral dimension of the gate cut contact structure is less than a lateral dimension of the self-aligned backside contact.

2. The nanosheet semiconductor structure according to claim 1, wherein the gate cut contact structure further comprises:
a contact liner; and
a contact fill.

3. The nanosheet semiconductor structure according to claim 2, wherein a portion of the contact liner is sandwiched between the source drain contact on a frontside and the contact fill of the gate cut contact structure.

4. The nanosheet semiconductor structure according to claim 2, wherein the contact liner of the gate cut contact structure directly contacts a top surface of the self-aligned backside contact.

5. The nanosheet semiconductor structure according to claim 1, wherein an RX liner physically separates and electrically isolates the self-aligned backside contact from a surrounding semiconductor layer.

6. The nanosheet semiconductor structure according to claim 1, wherein the self-aligned backside contact and an RX liner directly contact a top of a first backside wiring layer.

7. A nanosheet semiconductor structure comprising:
a self-aligned backside contact; and
a gate cut contact structure extending between two stacks stack of semiconducting layers and in electrical contact with the self-aligned backside contact and a source drain contact on a frontside, wherein a lateral dimension of the gate cut contact structure is less than a lateral dimension of the self-aligned backside contact.

8. The nanosheet semiconductor structure according to claim 7, wherein the gate cut contact structure further comprises:
a contact liner; and
a contact fill.

9. The nanosheet semiconductor structure according to claim 8, wherein a portion of the contact liner is sandwiched between the source drain contact on a frontside and the contact fill of the gate cut contact structure.

10. The nanosheet semiconductor structure according to claim 8, wherein the contact liner of the gate cut contact structure directly contacts a top surface of the self-aligned backside contact.

11. The nanosheet semiconductor structure according to claim 7, wherein an RX liner physically separates and electrically isolates the self-aligned backside contact from a surrounding semiconductor layer.

12. The nanosheet semiconductor structure according to claim 7, wherein the self-aligned backside contact and an RX liner directly contact a top of a first backside wiring layer.

13. A nanosheet semiconductor structure comprising:
a shallow trench isolation region arranged between a first stack of semiconducting layers and a second stack of semiconducting layers;
a self-aligned backside contact, wherein a lateral width of the self-aligned backside contact is substantially equal to a lateral width of the shallow trench isolation region; and
a gate cut contact structure extending from the self-aligned backside contact to a source drain contact on a frontside through the shallow trench isolation region.

14. The nanosheet semiconductor structure according to claim 13, wherein the gate cut contact structure further comprises:
a contact liner; and
a contact fill.

15. The nanosheet semiconductor structure according to claim 14, wherein a portion of the contact liner is sandwiched between the source drain contact on a frontside and the contact fill of the gate cut contact structure.

16. The nanosheet semiconductor structure according to claim 14, wherein the contact liner of the gate cut contact structure directly contacts a top surface of the self-aligned backside contact.

17. The nanosheet semiconductor structure according to claim 13, wherein an RX liner physically separates and electrically isolates the self-aligned backside contact from a surrounding semiconductor layer.

18. The nanosheet semiconductor structure according to claim 13, wherein the self-aligned backside contact and an RX liner directly contact a top of a first backside wiring layer.

19. The nanosheet semiconductor structure according to claim 13, wherein an RX liner lines sidewalls of both the shallow trench isolation region and the self-aligned backside contact.
